(19) United States
(12) Patent Application Publication
(10) Pub. No.: US 2010/0164324 A1
(43) Pub. Date: Jul. 1, 2010

(54) SELF-SENSING DIELECTRIC ACTUATOR SYSTEM

(75) Inventors: Kwang J. Kim, Reno, NV (US); Kwangmok Jung, Gyungbuk (KR)

Correspondence Address: HOLLAND & HART, LLP, P.O BOX 8749, DENVER, CO, 80201, US

(73) Assignee: BOARD OF REGENTS, UNIVERSITY OF NEVADA, RENO, Reno, NV (US)

(21) Appl. No.: 12/670,362

(22) PCT Filed: Jul. 22, 2008
(86) PCT No.: PCT/US08/70779

§ 371 Date: Feb. 4, 2010

Related U.S. Application Data
(60) Provisional application No. 60/961,801, filed on Jul. 23, 2007.

(51) Int. Cl. H01L 41/107

(52) U.S. Cl. 310/318

(57) ABSTRACT

A self-sensing dielectric actuator system. The system has a deformable dielectric material between two electrodes. A relatively low frequency actuating signal is applied to the electrodes and thereby causes the dielectric material to deform, moving at least one electrode. A relatively high frequency sensing signal applied across the electrodes indicates how far the electrode has moved. The system may be calibrated by using a laser or other sensor to mechanically measure the amount of movement. An object may be displaced a desired distance by coupling the object to the electrode and using the sensing signal to measure how far the object has moved.

This patent application claims priority from U.S. Provisional Patent Application No. 60/961,801 filed 23 Jul. 2007, the entire content of which is incorporated herein by this reference.

### BACKGROUND

Various actuators, such as electrical motors, pneumatic or hydraulic cylinders, and magnetic solenoids are commonly used in many types of engineering disciplines and applications. Typically, actuators are operable to displace one object relative to another object. The magnitude of the displacement of an actuator generally is an important factor in the operation of engineering systems, such as feedback control systems that use closed-loop control. In closed-loop control, the displacement of an actuator is typically measured by a sensor coupled to the actuator. Sensors can include instruments such as angular encoders and tachometers that can measure angular displacement, and linear displacement sensors such as linear encoders and variable differential transformers.

Many complex control systems such as robotic systems use multiple actuators. A separate sensor is needed for each actuator. The more actuators and sensors, the bulkier and more cumbersome the system becomes. This problem becomes particularly acute in systems designed for micro- to meso-scale applications. For example, robotic systems that mimic the motion of small animals such as insects, earthworms, and centipedes, must accommodate many axes of motion in a very small space, and this becomes very difficult as the number of actuators and sensors increases.

One approach to this problem has been to minimize the size of the sensors. For example, a dielectric elastomer (DE) has been analyzed in sensing applications. In one known method, the capacitive sensing response of a DE was researched. In another known method, the dynamic-stretch response and corresponding capacitance response due to a voltage applied to a DE membrane between two compliant electrodes was studied. See “Response of Dielectric Elastomer Actuators”, Sommer-Larsen et al., p. 157, Smart Structures and Materials 2001: Electroactive Polymer Actuators and Devices, Bar-Cohen (ed.), Proceedings of SPIE Vol 4329 (2001)

There have been attempts to develop an actuator that can double as its own sensor. Such a device would eliminate the need for a separate sensor. For example, in an actuator of the kind having a DE that deforms under the influence of an electric field, the variable conductivity of coated compliant electrodes was measured as the actuator expanded. The displacement of the actuator was indicated by a measured change in the conductivity of the electrodes. However, this device had a bandwidth of less than 0.2 Hz and a displacement measurement error of greater than 5%.

There is still a need for an actuator that can accurately and rapidly sense its own displacement.

### SUMMARY OF THE INVENTION

In one aspect, an embodiment of the invention provides a self-sensing dielectric actuator system. The system has a deformable first electrode and a second electrode spaced apart from the first electrode. A dielectric material is disposed between the electrodes. An actuating signal source applies an electric potential to the electrodes and thereby causes the dielectric material to deform the first electrode. A sensing signal source applies a sensing signal across the electrodes, and a sensing element is used to measure any change in the sensing signal caused by a deformation of the first electrode.

In another aspect, an embodiment of the invention provides a method of sensing motion of an actuator of the kind having a deformable dielectric between two electrodes. An actuating signal is applied across the dielectric. A sensing signal is also applied across the dielectric. Any change in the sensing signal as the dielectric deforms under influence of the actuating signal is measured

In another aspect, an embodiment of the invention provides a method of mechanically displacing an object a desired distance. This method includes coupling the object to a deformable first electrode, applying an actuating signal across the first electrode and a second electrodes to generate an electric field across a deformable dielectric disposed between the electrodes, applying a sensing signal across the dielectric, measuring any change in the sensing signal as the first electrode deforms, and adjusting the actuating signal according to the measured change in the sensing signal to displace the object the desired distance.

Further aspects of the invention will become apparent from the following description and drawings, describing and illustrating by examples the principles of the invention.

### BRIEF DESCRIPTION OF THE DRAWINGS

FIG. 1 is a perspective view of a dielectric actuator according to a first embodiment shown in an OFF state.

FIG. 2 is a perspective view of the dielectric actuator of FIG. 1 but shown in an ON state.

FIG. 3 is a perspective view of the dielectric actuator of FIG. 1 with a sensing element.

FIG. 4 is a schematic diagram of a dielectric actuator in a circuit having a signal mixer for mixing an actuating signal input with a sensing signal input.

FIG. 5 is a schematic diagram of a dielectric actuator connection with a sensing element, depicted as a voltage divider circuit.

FIG. 6 is a schematic diagram of a dielectric actuator connection with a sensing element, depicted as a high-pass filter circuit.

FIG. 7 is a chart illustrating a shift in the magnitude of the output voltage of the circuit of FIG. 4 due to capacitive reactance change when the actuator goes between its OFF and ON states.

FIG. 8 is a chart illustrating, for capacitive reactance when the actuator is OFF and when it is ON, output magnitude shift in the circuit of FIG. 6 as a function of frequency.

FIG. 9 is a schematic diagram of a dielectric actuator according to a second embodiment electrically connected in a schematically illustrated circuit having a signal mixer, signal amplifier and oscilloscope.

FIG. 10 is a chart illustrating measured output voltages for corresponding actuation voltages applied to the circuit of FIG. 9.

FIG. 11 is a chart illustrating the measured peak-to-peak output voltage versus the frequency of the sensing voltage applied to the circuit of FIG. 9 for resistors of various values.

FIG. 12 is a chart illustrating the measured decibel level of the output voltage versus the frequency of the sensing voltage applied to the circuit of FIG. 9 for resistors of various values.

FIG. 13 is a schematic diagram of a dielectric actuator shown electrically connected in a schematically illustrated circuit having a signal mixer, signal amplifier, laser sensor, peak detector, microcontroller and computing device.

FIGS. 14, 15 and 16 are charts illustrating an actuation input voltage applied to the physical implementation of FIG. 13 compared to the measured output voltage and displacement of the actuator for specific sensing input voltage frequencies.

FIGS. 17, 18 and 19 are charts illustrating a square actuation input voltage applied to the physical implementation of FIG. 13 compared to the measured output voltage and displacement of the actuator for specific sensing input voltage frequencies.

FIG. 20 is a chart illustrating the measured output voltage verses the measured displacement of the actuator for a given range of actuation input voltages applied to the physical implementation of FIG. 13.

FIG. 21 is a flowchart illustrating a method of sensing motion of an actuator according to an embodiment of the invention.

FIG. 22 is a flowchart illustrating a method of mechanically displacing an object according to an embodiment of the invention.

### DESCRIPTION OF THE EMBODIMENTS

Several embodiments of a self-sensing actuator are described. Some embodiments use an electro-active polymer such as a dielectric elastomer (DE) for a dielectric. A self-sensing actuator according to the principles of the invention is simultaneously operable as an actuator and a sensor without additional independent sensing devices or additional electrodes.

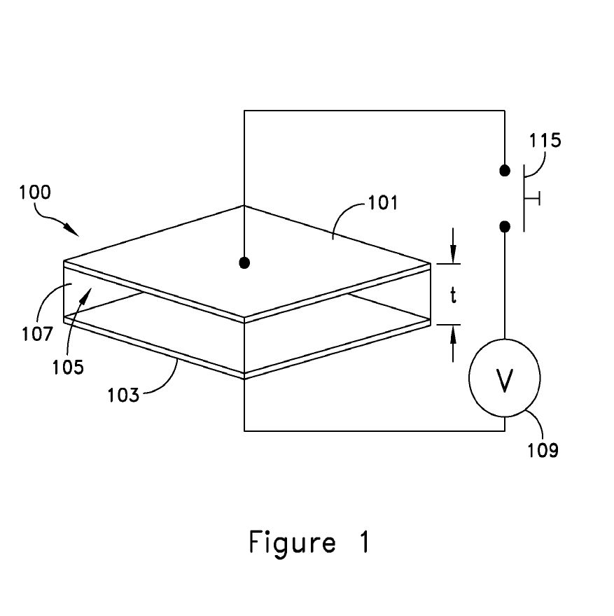

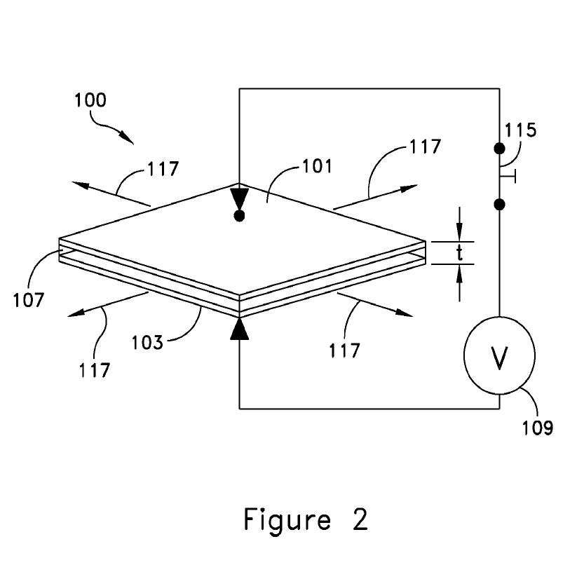

An embodiment of a self-sensing dielectric actuator system 100 is shown in FIGS. 1 and 2. A deformable first electrode 101 is separated from a second electrode 103 by a space 105. The second electrode may also be deformable. A dielectric material 107, for example a dielectric elastomer (DE), is disposed in the space 105 between the electrodes. The electrodes may be separate sheets of material or they may be formed on opposing surfaces of the dielectric material.

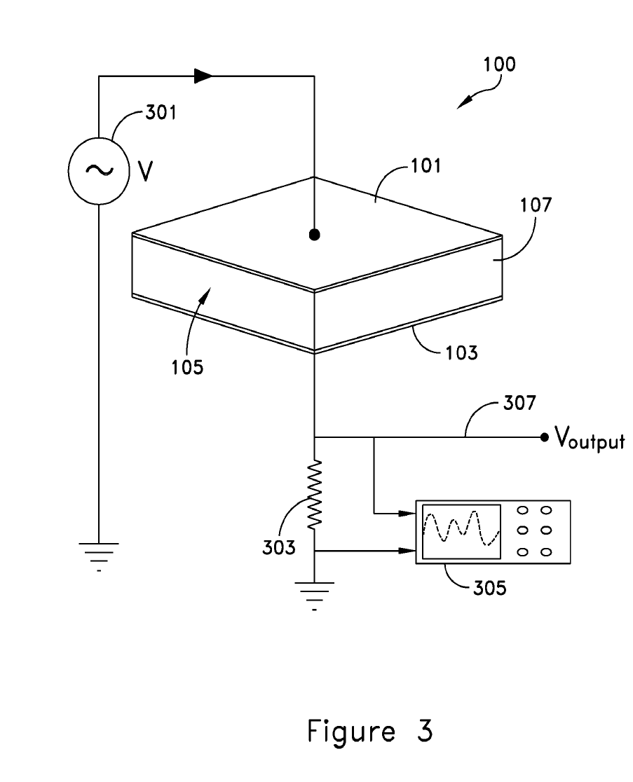

An actuating signal source 109 is configured to apply an electric potential across the electrodes and thereby cause the dielectric material to deform the first electrode. As shown in FIG. 3, a sensing signal source 301 is configured to apply a sensing signal across the electrodes. A sensing element 303, for example an impedance element such as a resistor in series with the sensing signal source 301 and the actuator 100, is used to measure any change in the sensing signal caused by a deformation of the first electrode.

FIGS. 1 and 2 show the actuator system 100 in an OFF state and an ON state, respectively. The actuating signal source 109 is electrically coupled to the electrodes when a series-connected switch 115 is closed. The actuating source 109 is operable to apply a predetermined voltage across the electrodes 101 and 103 to place the actuator 100 in the ON state. With the switch closed the actuating signal introduces an electric field within the dielectric material 107, causing it to deform. In this embodiment the dielectric material compresses with respect to its thickness and expands with respect to its area, as indicated by arrows 117, compared to its OFF state. The dielectric material 107 compresses in a direction generally parallel to the direction of the resultant electrical field, i.e., substantially perpendicular to the electrodes 101 and 103, resulting in the deformable electrode 101 moving toward the other electrode 103. If both electrodes are deformable, they move toward each other. Correspondingly, the dielectric material 107 expands in a direction perpendicular to the electrical field, parallel to the electrodes.

A change in the sensing signal as detected across the sensing element 303 may be observed or interpreted by means of an instrument such as an oscilloscope 305 coupled to the sensing element 303.

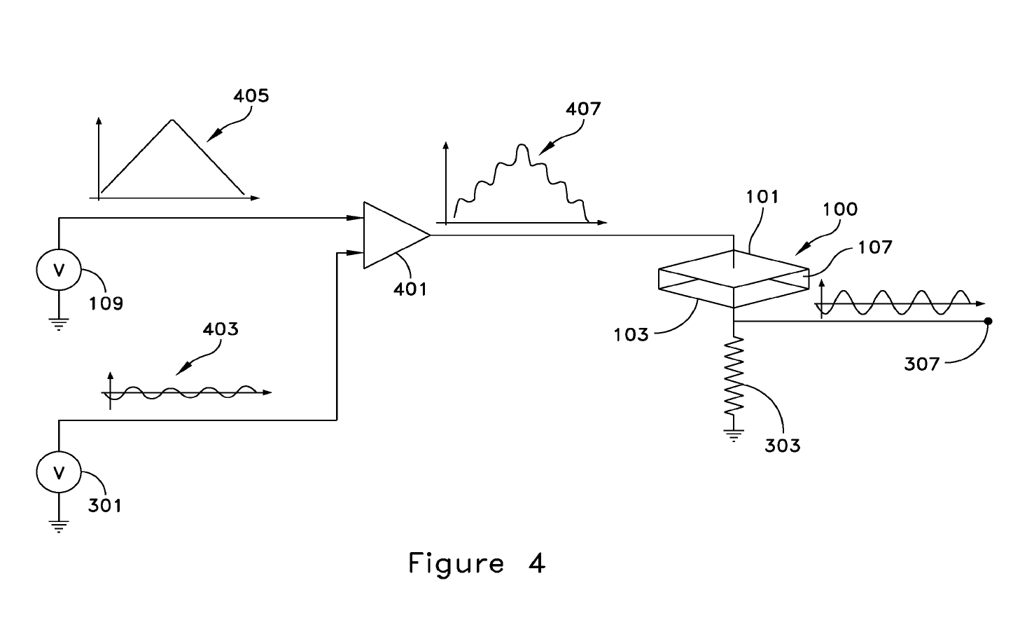

In some embodiments a mixer 401 as shown in FIG. 4 receives the sensing signal 403 from the sensing signal source 301 and the actuating signal 405 from the actuating signal source 109 and provides a mixed signal 407 for application to the electrodes. The mixer 401 may comprise a general non-inverting summation operation amplifier circuit. The mixer modulates the actuating signal 405 with the sensing signal 403 using any of various mixing or summation functions. Accordingly, the mixed signal 407 from the mixer 401 applied to the actuator 100 has both an actuating component and a sensing component.

The actuating component of the mixed signal 407 has a relatively large amplitude to deform the actuator 100. The sensing component of the mixed signal has a high frequency to flow through the effective high-pass filter formed by the actuator 100 and the sensing element 303. When the mixed signal is applied to the actuator, the actuation component is damped out due to its low frequency and the output signal at the output 307 comprises the high frequency of the sensing component. Generally, the amplitude of the sensing component of the mixed signal is sufficiently lower than that of the actuating component to prevent the sensing component from significantly deforming the actuator.

In the embodiment shown FIGS. 1 through 4, the electrodes are shaped as parallel rectangular plates, but other shapes and dispositions of the electrodes and the dielectric may be used as convenient.

Because the electrostatic force causes contractions in the electrical field direction, the effective compression pressure σ_{z} necessary to deform the dielectric material can be derived as follows:

σ_{z}=−εₒ εᵣ (V/t)²=−εₒ εᵣ E² (1)

where E is the imposed electric field, t is the final thickness of the dielectric material, V is the applied voltage, and εₒ and εᵣ are the vacuum permittivity and the relative permittivity of the dielectric material, respectively.

In general, the self-sensing actuator 100 can be modeled according to an electrical capacitance model as follows:

C=εₒ εᵣ (A/t) (2)

where C is the capacitance of the actuator, A is the area of each electrode 101, 103 and t is the thickness of the dielectric material 107, respectively. As shown in Equation 2, the capacitance C is directly related to the electrode area A and inversely related to the film thickness t. In the ON state, the capacitance C is increased because the area A is increased and the thickness t is decreased.

The difference between the capacitance C of the actuator in the OFF state versus the capacitance C in the ON state can be determined by comparing the amplitude of the sensing signal at the output voltage point 307 (Vₒᵤₜₚᵤₜ) when the actuator is in the OFF state with the amplitude of the sensing signal at the output voltage point 307 (Vₒᵤₜₚᵤₜ) when the actuator is in the ON state.

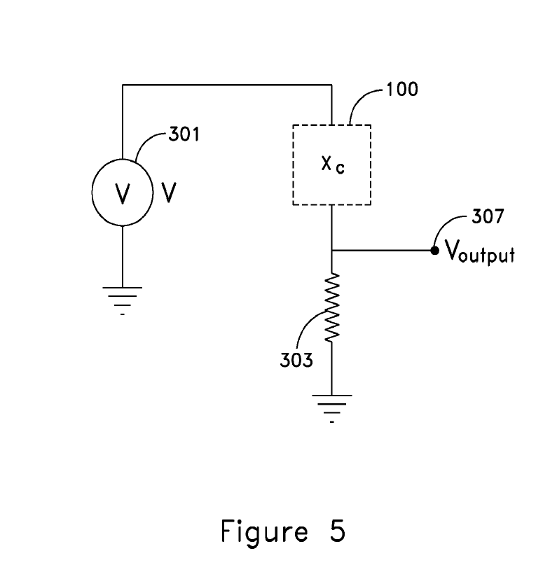

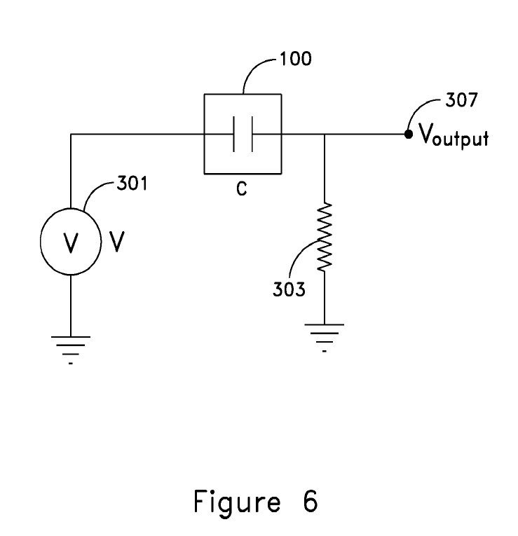

The circuit of FIG. 3 can be modeled as either of (1) a voltage divider circuit as shown in FIG. 5, or (2) a high-pass filter circuit as shown in FIG. 6.

The voltage divider circuit model is shown in FIG. 5. In the voltage divider circuit model, the capacitive reactance X_{c} is a function of the frequency of the sensing signal as follows:

X_{c}=1/(2πFC) (3)

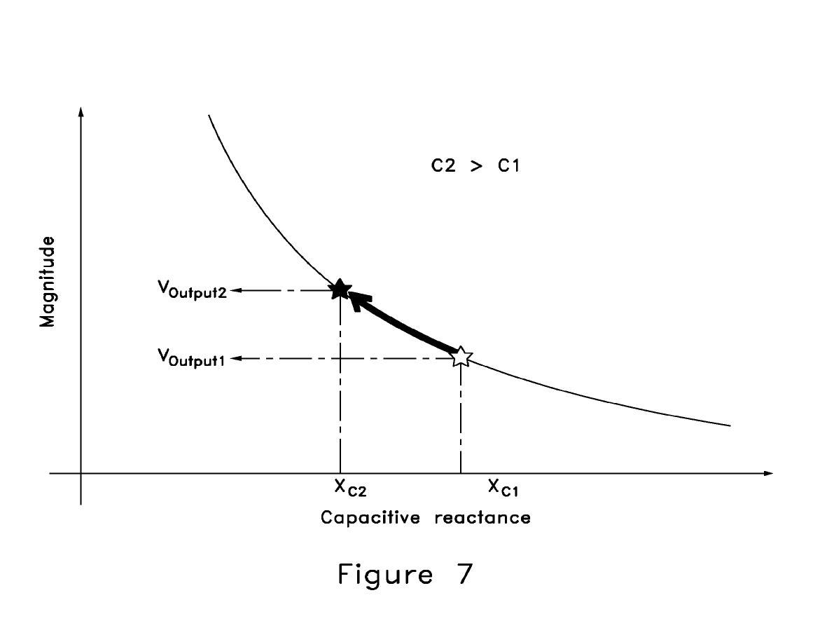

Vₒᵤₜₚᵤₜ=R·Vᵢₙₚᵤₜ/(R+X^{c}) (4)

where F is the frequency of the input signal and C is the capacitance of the actuator 100. Referring to Equation 3, if the input frequency F is fixed, then the capacitive reactance X_{c} is inversely proportional to the capacitance C. Accordingly, the capacitive reactance X_{c} decreases when the actuator expands, and the measured amplitude of the output voltage Vₒᵤₜₚᵤₜ is proportional to the amount of expansion of the actuator. FIG. 7 graphically depicts this shift in voltage output magnitude due to the change in capacitive reactance.

The high-pass filter circuit model is shown in FIG. 6. The high-pass filter circuit can be defined according to the following equations:

F_{c}=1/(2πRC) (5)

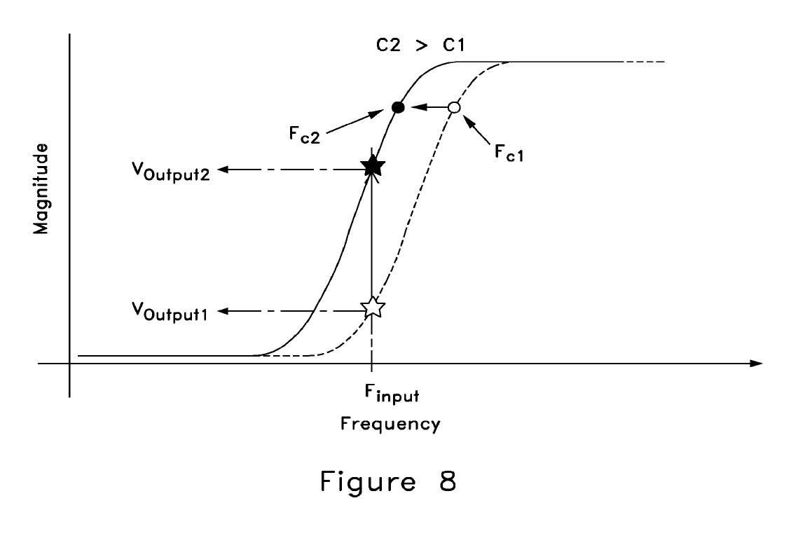

Aᵥ=1/(1+(F_{c}/Fᵢₙₚᵤₜ)²)^{1/2} (6)

where F_{c} is the cut-off frequency of the high-pass filter and Aᵥ is the gained voltage of the high-pass filter, where 0<Aᵥ<1. According to Equation 5, the cut-off frequency F_{c} is inversely proportional to the capacitance C. As shown graphically in FIG. 8, the cut-off frequency F_{C1} is shifted to F_{C2} when the capacitance C increases from a first capacitance C1 with the actuator in a first state to a second capacitance C2 with the actuator is a second state that is expanded relative to the first state. The change in capacitance from C1 to C2 causes the gained voltage Aᵥ to increase. Accordingly, the magnitude of the output voltage Vₒᵤₜₚᵤₜ increases at a fixed input frequency Fᵢₙₚᵤₜ.

Regardless of whether the voltage divider circuit or the high-pass filter circuit is used as a model, the amplitude of the output voltage Vₒᵤₜₚᵤₜ is proportional to the expansion of the actuator. Therefore, the variation of the voltage amplitude of the output voltage Vₒᵤₜₚᵤₜ as measured across the sensing element 303 can be monitored to determine the expansion of the actuator.

If it is desired for the actuator to deform through a certain distance and then remain in a fixed position, a DC actuating signal would be applied. If it is desired that the actuator deform in a time-varying way, then a varying actuating signal would be used. The value of the sensing element 303 should be selected so that, in combination with the capacitance of the actuator, variations in the actuation signal are filtered out by the high-pass filter effect of the actuator and sensing element. These variations should not be present in the output signal Vₒᵤₜₚᵤₜ.

Conversely, the sensing signal must be at a sufficiently high frequency as not to be filtered out, such that changes in the sensing signal, corresponding with changes in the displacement of the actuator, are present in the output signal.

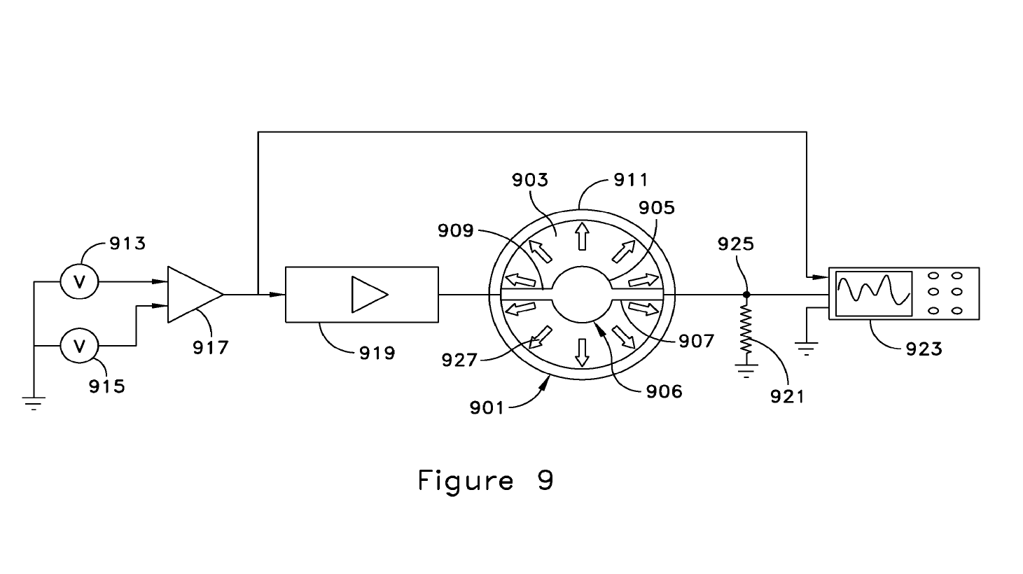

Working embodiments of a self-sensing actuator system similar to the embodiment described above were constructed and tested. One such embodiment is depicted schematically in FIG. 9. An actuator generally 901 has a dielectric material 903 made of Silicone CF19-2186, manufactured by NuSil Technology LLC. A first electrode 905 was made of conductive silver grease CW7100, manufactured by ITW Chemtronics. The electrode 905 is shown disposed on top of the dielectric 903. The electrode 905, rather than being rectangular in shape as in the embodiment shown in FIGS. 1 through 4, is generally circular in shape with an elongated terminal 907 extending radially away from the electrode. Similarly, a second electrode 906 having a shape similar to that of the electrode 905 is disposed beneath the dielectric 903. This second electrode 906 is hidden from view by the electrode 905, but it too has an elongated terminal 909 which in FIG. 9 can be seen through the dielectric. Both electrodes are deformable.

The dielectric 903 is formed as a film with a thickness t of approximately 75 Am when the actuator is in the OFF state. The dielectric was fabricated by spin-coating, pre-stretched 30% in the radial direction and mounted on a cylindrical rigid frame 911 with an inner diameter approximately 100 mm. Each electrode has an approximately 15 mm diameter and is positioned at the approximate center of the dielectric.

An actuator signal source 913 and a sensing signal source 915 communicate their respective signals to a mixer 917. The mixer 917 communicates its mixed signal to a control circuit 919 which includes an operational amplifier such as high voltage amplifier 609E-6 manufactured by Trek, Inc. An output from the control circuit 919 is connected to the terminal 909 of the electrode 906.

The terminal 907 of the electrode 905 is connected to a sensing element 921 and to an input of a measuring instrument 923, in this case a digital oscilloscope model TDS210 manufactured by Tektronix, Inc. The mixed signal from the mixer 917 was also supplied to the oscilloscope so that both input and output sensing signals could be monitored. Expansion of the dielectric 903 when the actuating signal is applied is indicated generally by arrows 927, showing expansion radially from the center. Compression of the dielectric, such that the electrodes 905 and 906 move closer to each other, also takes place but is not depicted in the drawing.

A 10 megohm resistor was used as the sensing element 921. The AC sensing signal was generated by a function generator, represented schematically as the voltage source 915, and had a 300 peak-to-peak voltage (Vpp) amplitude and a 100 Hz frequency. In one implementation, the actuating signal had a voltage of 2.2 kV. In another implementation, the actuating signal had a voltage of 3 kV. The voltages for the actuating signal and the sinusoidal wave for the sensing signal were combined by the mixer 917.

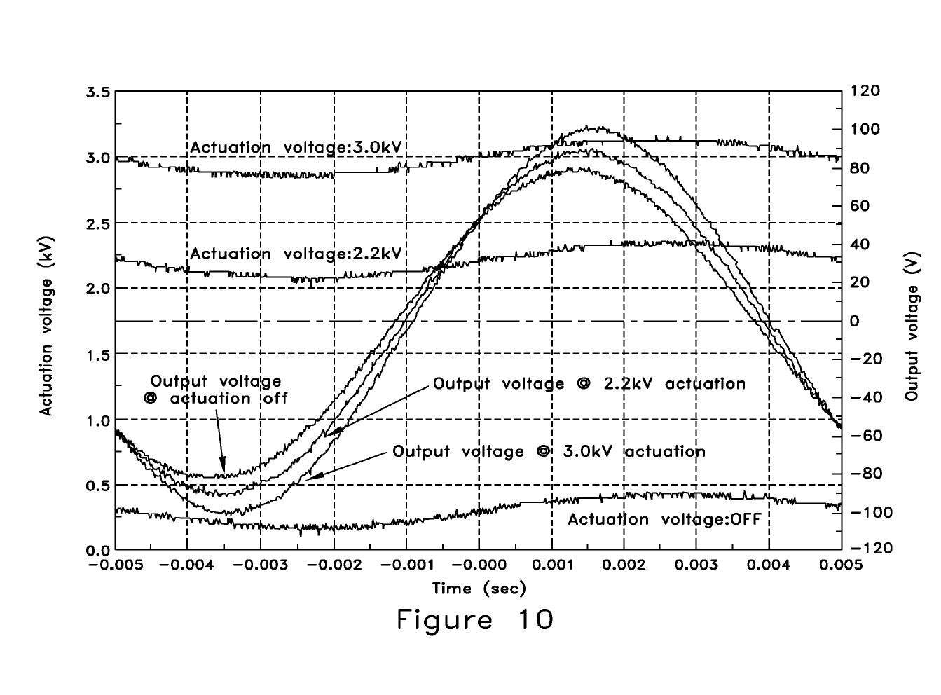

The sinusoidal component of the measured output voltage Vₒᵤₜₚᵤₜ at the node 925 is shown graphically in FIG. 10. Only the sensing signal component is shown because the actuating voltage is damped by the high pass filter effect of the actuator. Measured output voltages Vₒᵤₜₚᵤₜ for actuating voltages of 0, 2.2 kV and 3.0 kV are shown. With respect to each other, the measured output voltages Vₒᵤₜₚᵤₜ have nearly negligible phase shifts and relatively small variations in magnitude.

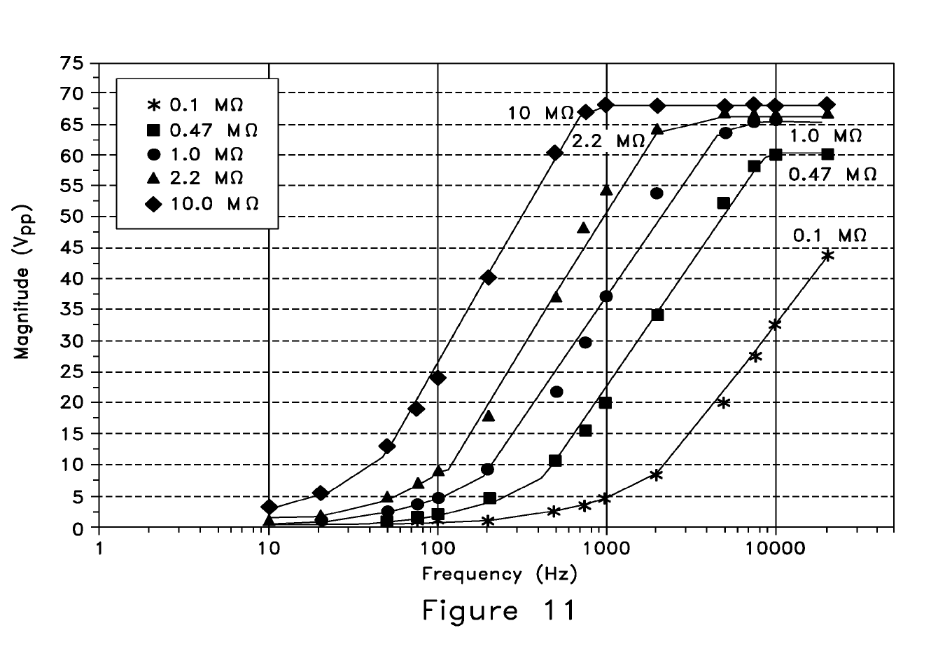

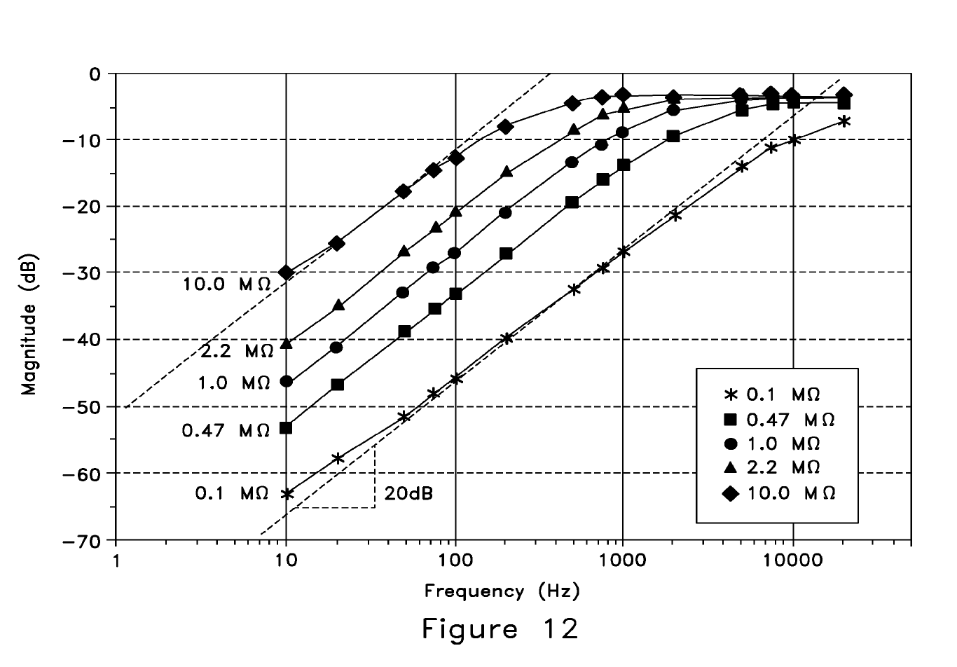

In other implementations resistors having values of 0.1, 0.47, 1, 2.2, and 10 megohms were used as the sensing element 921. For each implementation, sinusoidal sensing signals having 100 Vpp amplitude and various frequencies were applied to the actuator. The output voltages Vₒᵤₜₚᵤₜ for each resistor value and input voltage frequency value are shown graphically in FIGS. 11 and 12.

According to the results shown in FIGS. 10 through 12, the DE actuators 10 and 110 configured with resistors as sensing elements follow the general characteristics of a passive RC high-pass filter. For example, the voltage output Vₒᵤₜₚᵤₜ signals are damped within a low frequency range. The slopes of the curves that correspond with the various resistor values are substantially the same.

Referring to FIGS. 11 and 12, the magnitude of the measured voltage output Vₒᵤₜₚᵤₜ signals are attenuated within a high frequency range. This condition is due to the inherent material limitations of silicone. Generally, silicone is not an ideal dielectric material for a capacitor because it can conduct small amounts of current. Accordingly, the charge on the DE actuator 110 eventually leaks off, which leads to the signal attenuation condition, or damping phenomena, within a high frequency range. However, such effects at the extreme upper end of the frequency range do not discount the results shown in FIGS. 11 and 12 because the results of the working implementations focus on frequency ranges where magnitude is proportional to frequency, and this is not at the upper end of the frequency range.

The above-described actuators provide simultaneous actuating functionality and sensing functionality by mixing an actuating input signal with a sensing signal. Such functionality is accomplished by attenuating the output of the actuating signal and detecting the output of the sensing signal. As described above, the actuating signal can be attenuated by the actuator itself, which acts as a high-pass filter. In addition to the actuator, a separate high-pass filter can be electrically coupled to the actuator to attenuate or further attenuate the output of the actuating signal.

The actuator attenuates the output of actuating signals within a predetermined frequency range, which is typically a lower range. However, the predetermined actuating signal attenuation range can include higher frequencies if sensing elements comprising resistors with smaller resistances are used. As shown in FIGS. 11 and 12, a larger resistance results in saturation of the output magnitude at a lower frequency than smaller resistances. Typically, smaller resistances are better when using a high frequency for sensing. Therefore, if smaller resistances are used, the available actuating signal frequency bandwidth, that is, the range in which the actuating signal output is attenuated by the actuator, is wider than if larger resistances are used.

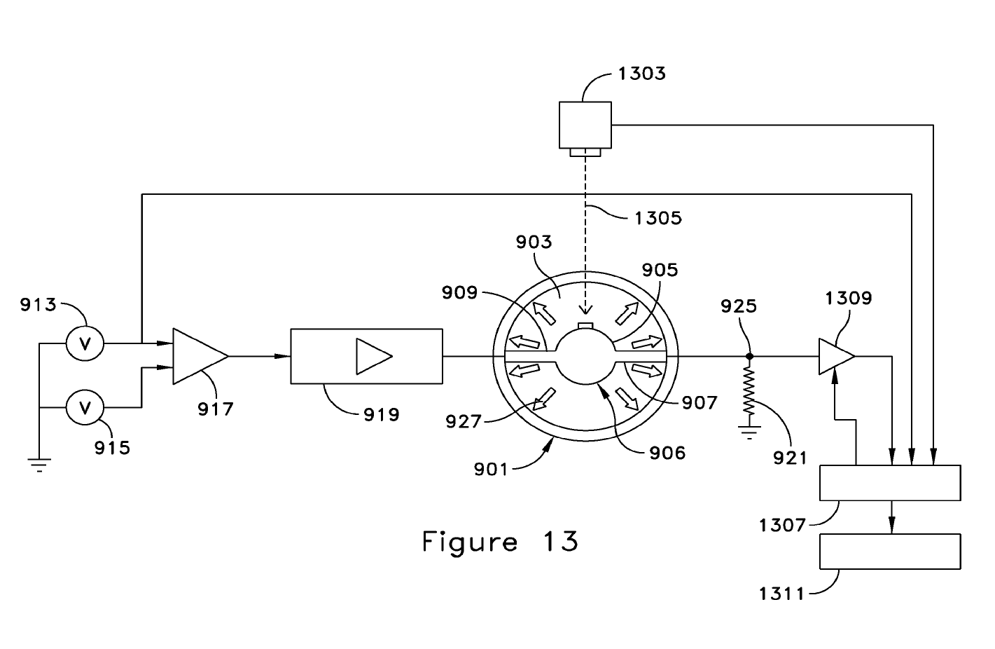

According to another working embodiment, the correlation between the variation in a sensing signal output voltage and the actual displacement of a self-sensing actuator was tested. This embodiment is illustrated schematically in FIG. 13. Portions of this embodiment are similar to the embodiment shown in FIG. 9 and for convenience those components that are similar in both drawings have the same reference numerals and will not be further described.

The actuator system 901 has a reflecting target 1301 affixed to any convenient location that moves when the system is actuated. In the embodiment illustrated, the target 1301 is affixed to the electrode 905. A laser sensor 1303 such as a laser displacement sensor PC1401, manufactured by Micro-Epsilon, directs an optical beam 1305 at the target 1301 and receives a reflected optical beam in reply. An output of the laser sensor 1303 is provided to a microcontroller 1307 such as a microcontroller c8051F340, manufactured by Silicone Lab.

A peak detector 1309 receives the output sensing signal from the node 925. The peak detector includes positive and negative peak detecting functions to facilitate detection of an absolute magnitude of the sinusoidal sensing output signal at the node 925. The microcontroller 1307 is in communication with the peak detector 1309 and reads the absolute magnitude of the output sensing signal.

The microcontroller 1307 includes analog-to-digital converters that receive the actuating input signal, the peak detector output signal, and the laser sensor output signal. The microcontroller 1307 controls the peak detector 1309 to detect, hold, and reset the sinusoidal output signal. The microcontroller 1307 is programmed to act as a low pass filter to condition the received data and to communicate with and transfer data to a computing device such as a desktop or laptop computer 1311. The computing device 1311 is programmed to receive data from the microcontroller 1307 and save the data.

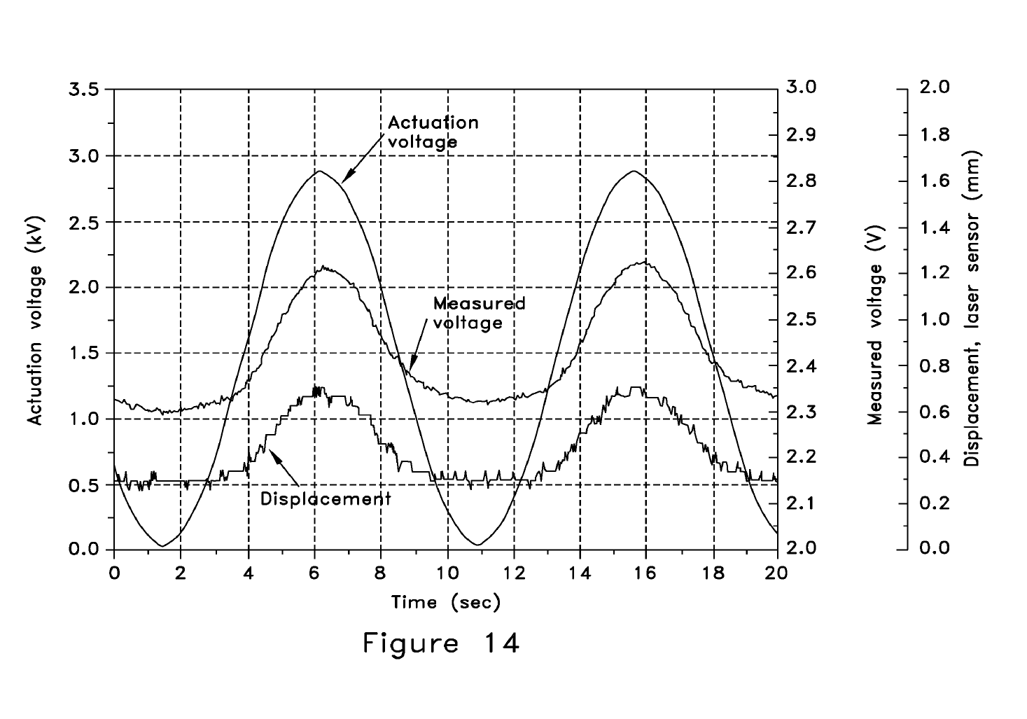

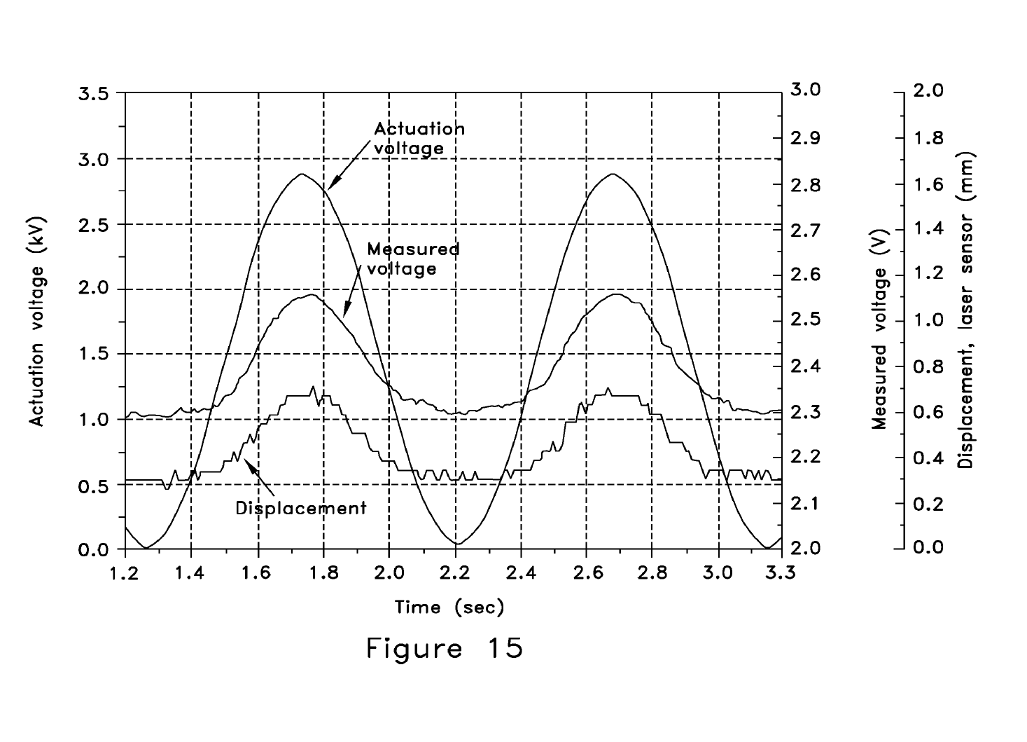

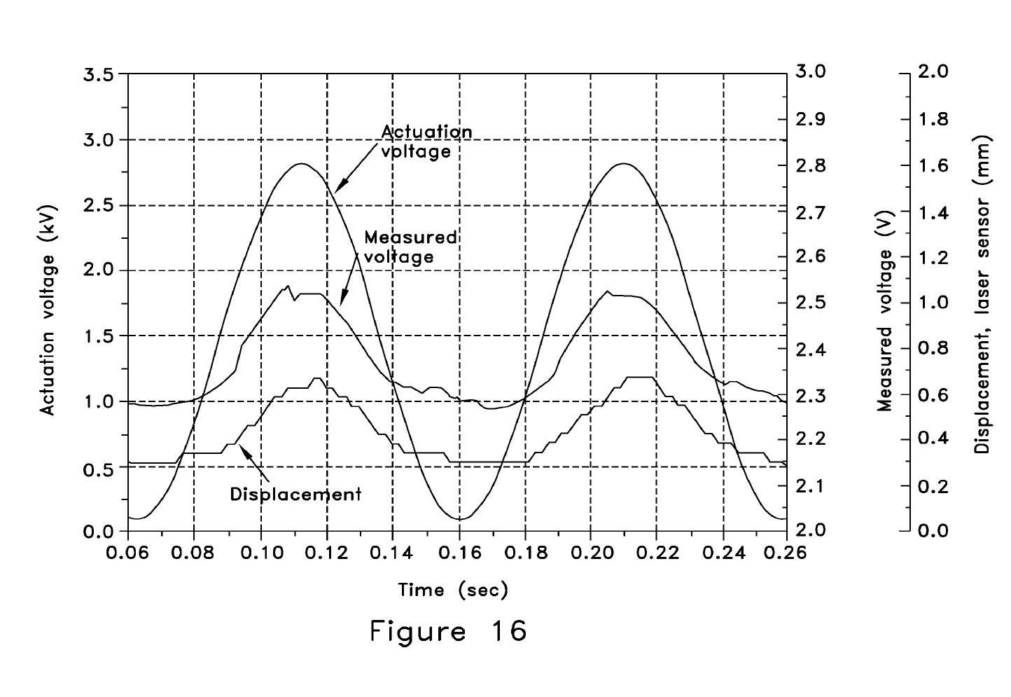

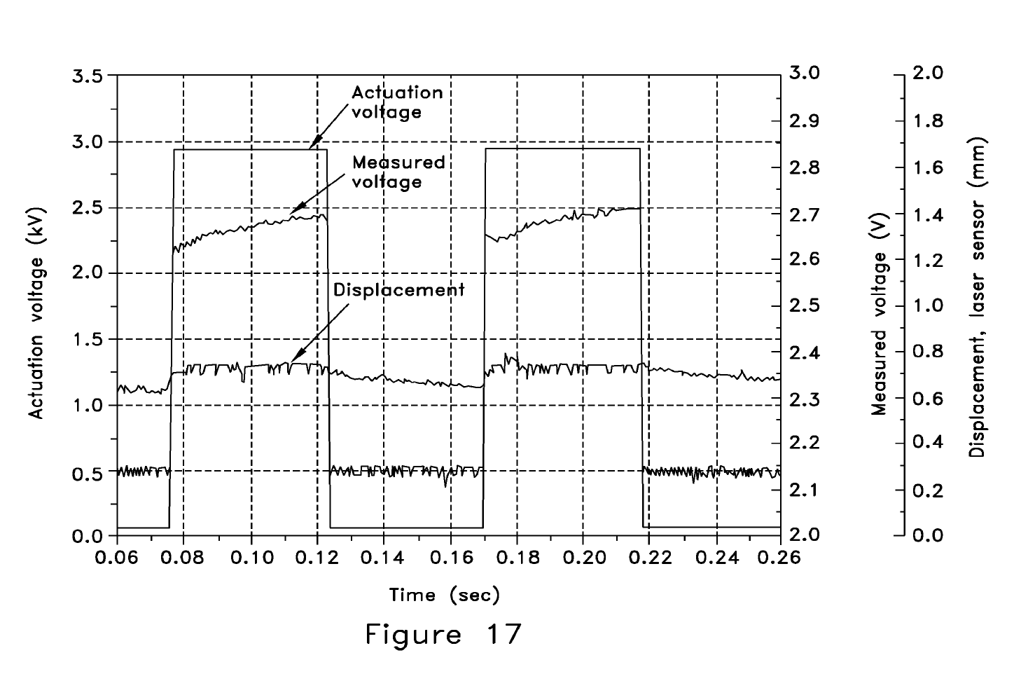

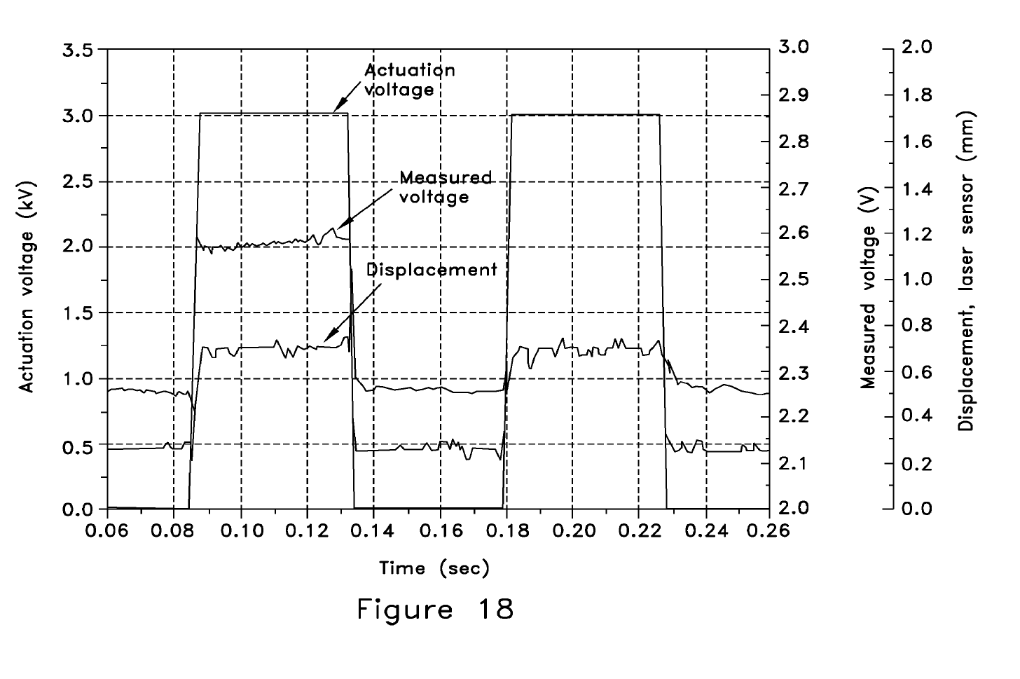

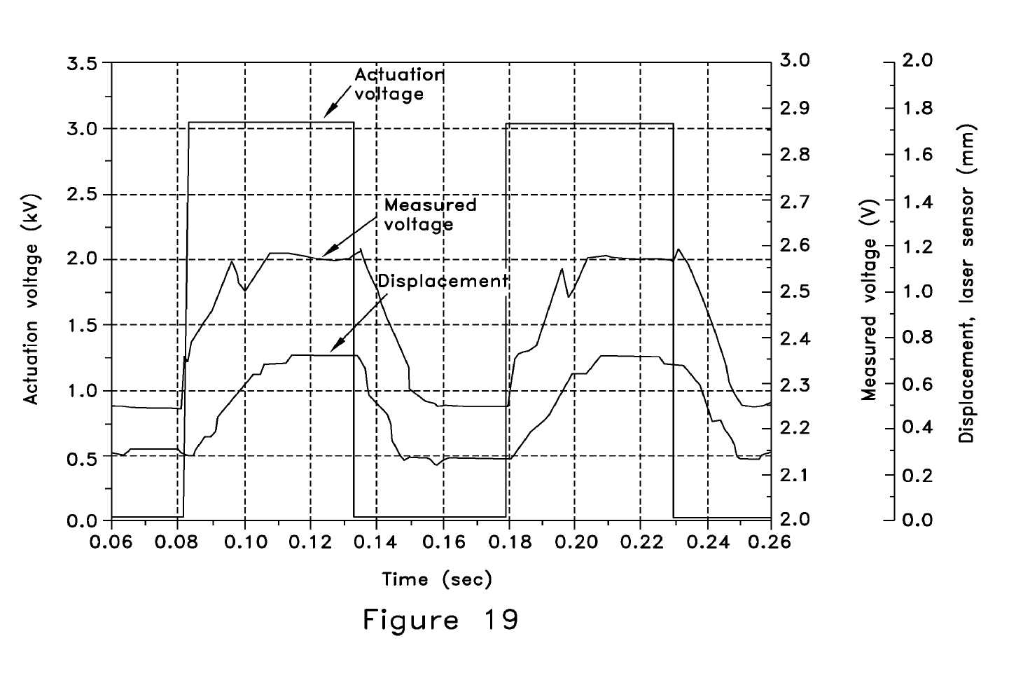

A sinusoidal sensing signal with 100 Vpp at 5 kHz was applied. In each of six implementations, the sinusoidal sensing signal was mixed with a respective sinusoidal actuating signal with a frequency of 0.1, 1, and 10 Hz, respectively, (see FIGS. 14-16) and a respective square actuating signal with a frequency of 0.1, 1, and 10 Hz (see FIGS. 17-19).

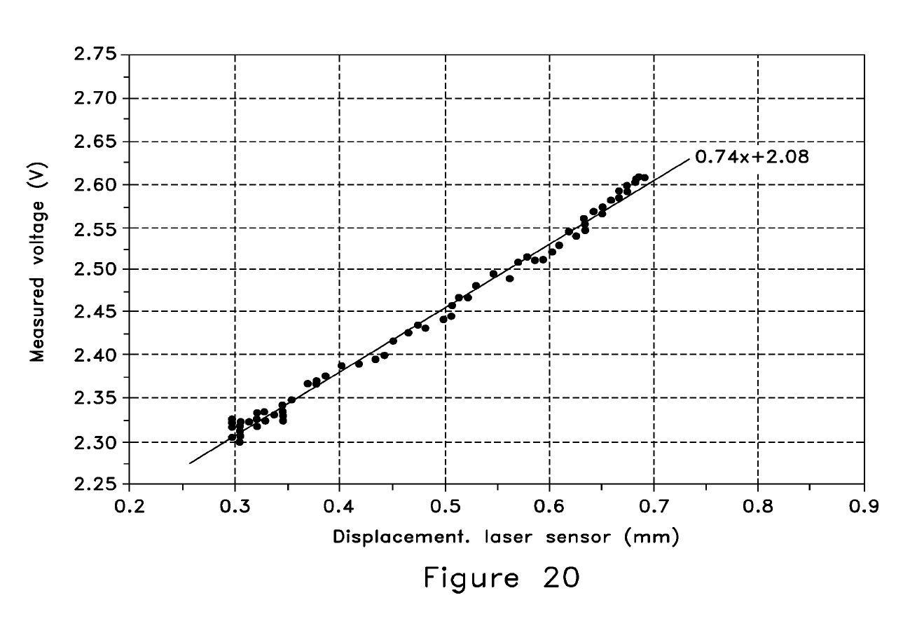

Referring to FIGS. 14-16, the measured sensing output voltages versus the actual displacements of the actuator for the various actuating signals are shown. The sensing output voltages are substantially consistent with the actual displacements. The fluctuations shown in FIGS. 14-16 are due to the inherent fast step input effects of a square wave. In order to avoid the effect of a fast step input on a square wave input, an applied slope input can be used. Moreover, referring to FIG. 20, the measured sensing output voltages appear to be more accurate than the results from the laser displacement sensors, which had a 50 μm dynamic measuring accuracy. As shown in FIG. 20, the results of the self-sensing actuator 901 and mixer 917 accurately fit a linear fitting function, e.g., 0.74x+2.08, between the voltage and the displacement. The parameters of the linear fitting function may be changed according to the mechanical and electrical properties of the particular dielectric material employed, such as electrode area, thickness and conductivity, and dielectric constant of the dielectric material.

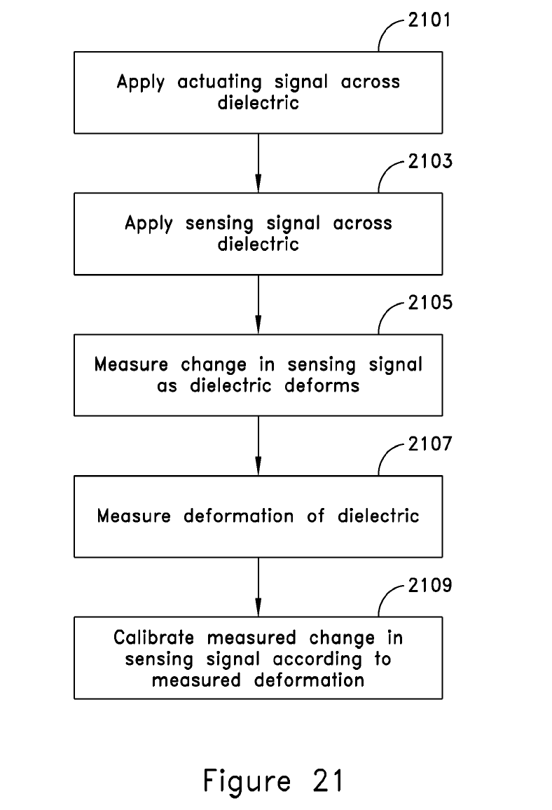

Turning now to FIG. 21, an embodiment of the invention provides a method of sensing motion of an actuator of the kind having a deformable dielectric between two electrodes. The method includes applying an actuating signal across the dielectric (2101), applying a sensing signal across the dielectric (2103), and measuring any change in the sensing signal as the dielectric deforms under influence of the activating signal (2105) Applying a sensing signal may comprise applying an alternating-current signal. Measuring a change in the sensing signal may comprise measuring the sensing signal across an impedance element.

The method may also include measuring a magnitude of the deformation of the dielectric (2107) and calibrating the measured change in the sensing signal according to the measured magnitude of the deformation (2109). Measuring the magnitude of the deformation may comprise sensing the deformation optically.

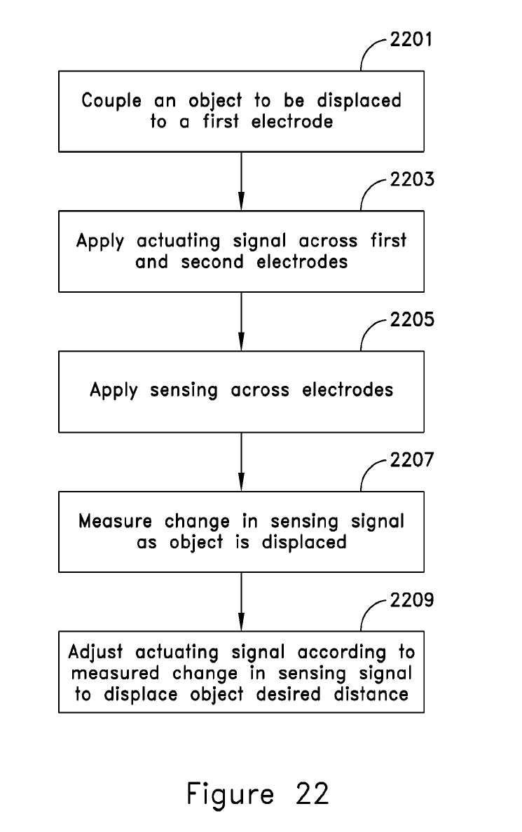

As shown in FIG. 22, an embodiment of the invention provides a method of mechanically displacing an object a desired distance. The method includes coupling the object to a deformable first electrode (2201), applying an actuating signal across the first electrode and a second electrode to generate an electric field across a deformable dielectric disposed between the electrodes (2203), applying a sensing signal across the electrodes (2205), measuring any change in the sensing signal as the dielectric deforms under influence of the actuating signal (2207), and adjusting the actuating signal according to the measured change in the sensing signal to displace the object a desired distance (2209). The method may also include calibrating the devices used in practicing the method, as has already been described with reference to the method illustrated in FIG. 21.

Accordingly, the self-sensing methods and apparatus described herein provide actuation sensing that accurately follows the actual displacement of the actuation. Therefore, in certain implementations, additional sensing devices or electrodes on the actuator are not required to sense the deformation of the actuator.

The self-sensing aspects of the actuator system herein described facilitate the construction and application of an effective feedback controllable actuation system. The actuator systems described herein may be employed in robotic systems, for example those involving very small devices. The actuator system can be used to actuate optical lenses in hand-held communication devices. The actuator system is suited for use in small, compact and lightweight applications. For example, the area A of the electrodes can be between 0.1 mm and 100 mm and the thickness t of the dielectric material can be between 0.01 mm and 1 mm.

In view of the many possible embodiments to which the principles of the disclosed actuator system may be applied, it should be recognized that the illustrated embodiments are only examples and should not limit the scope of the system.

1. A self-sensing dielectric actuator system comprising:
a deformable first electrode;
a second electrode spaced apart from the first electrode;
a dielectric material disposed between the electrodes;
an actuating signal source configured to apply an electric potential across the electrodes and thereby cause the dielectric material to deform the first electrode;
a sensing signal source configured to apply a sensing signal across the electrodes; and
a sensing element from which any change in the sensing signal caused by a deformation of the first electrode may be measured.

2. A system as in claim 1 wherein the sensor comprises an impedance element in electrical communication with the sensing signal source.

3. A system as in claim 1 wherein the sensor comprises an oscilloscope in electrical communication with the sensing signal source.

4. A system as in claim 1 wherein the sensor comprises a resistor in series with the sensing signal source and an oscilloscope that measures the sensing signal flow through the resistor.

5. A system as in claim 1 and further comprising a mixer that receives the sensing signal from the sensing signal source and the actuating signal from the actuating signal source and combines them for application to the electrodes.

6. A system as in claim 1 wherein the second electrode is deformable.

7. A system as in claim 1 wherein the electrodes comprise parallel plates.

8. A system as in claim 7 wherein the electrodes comprise generally disc-shaped coatings on opposite sides of the dielectric material and each electrode has an elongated terminal extending radially therefrom.

9. A system as in claim 1 and further comprising:
a measurement system that provides a measurement signal indicative of actual deformation of the first electrode; and
a controller responsive to the measurement signal and the sensing signal to provide a calibration of the sensing signal with respect to actual deformation of the first electrode.

10. A system as in claim 9 wherein the measurement system comprises a laser measurement system.

11. A method of sensing motion of an actuator of the kind having a deformable dielectric between two electrodes, the method comprising:
applying an actuating signal across the dielectric;
applying a sensing signal across the dielectric; and
measuring any change in the sensing signal as the dielectric deforms under influence of the actuating signal.

12. A method as in claim 11 wherein applying a sensing signal comprises applying an alternating-current signal.

13. A method as in claim 11 wherein measuring a change in the sensing signal comprises measuring the sensing signal across an impedance element.

14. A method as in claim 11 and further comprising:
measuring a magnitude of the deformation of the dielectric; and
calibrating the measured change in the semsing signal according to the measured magnitude.

15. A method as in claim 14 wherein measuring a magnitude of the deformation comprises sensing the magnitude with a laser sensor.

16. A method of mechanically displacing an object a desired distance comprising:
coupling the object to a deformable first electrode;
applying an actuating signal across the first electrode and a second electrodes to generate an electric field across a deformable dielectric disposed between the electrodes;
applying a sensing signal across the dielectric;
measuring any change in the sensing signal as the dielectric deforms under influence of the actuating signal; and
adjusting the actuating signal according to the measured change in the displacement signal to displace the object a desired distance.

17. A method as in claim 16 wherein applying a sensing signal comprises applying an alternating-current signal.

18. A method as in claim 16 wherein measuring a change in the sensing signal comprises measuring the sensing signal across an impedance element.

19. A method as in claim 16 and further comprising:
measuring a magnitude of the deformation of the dielectric; and
calibrating the measured change in the sensing signal according to the measured magnitude.

20. A method as in claim 19 wherein measuring a magnitude of the deformation comprises sensing the magnitude with a laser sensor.
